(19) United States
(12) Patent Application Publication
(10) Pub. No.: US 2026/0204313 A1
(43) Pub. Date: Jul. 16, 2026

(54) CHARGE TRAPPING FLASH NOR MEMORY IN MEMORY SYSTEMS

(71) Applicant: Micron Technology, Inc., Boise, ID (US)

(72) Inventors: Agostino Pirovano, Milan (IT); Innocenzo Tortorelli, Cernusco Sul Naviglio (IT); Lorenzo Fratin, Buccinasco (IT); Fabio Pellizzer, Boise, ID (US)

(21) Appl. No.: 19/431,843

(22) Filed: Dec. 23, 2025

Related U.S. Application Data
(60) Provisional application No. 63/744,740, filed on Jan. 13, 2025.

(51) Int. Cl. G11C 11/56

(52) U.S. Cl. CPC G11C 11/5642; G11C 11/5671

(57) ABSTRACT

Methods, systems, and devices for charge trapping flash NOR memory in memory systems are described. A memory system may include processing circuitry configured to perform one or more operations, a not-or (NOR) memory device coupled with the processing circuitry via a first interface, and a volatile memory device coupled with the NOR memory device via a second interface and the processing circuitry. Accordingly, the NOR memory device may be configured to provide first data, such as one or more model parameters for an artificial intelligence model, to the processing circuitry via the first interface as part of performing a first operation of the one or more operations. The volatile memory device may be configured to communicate second data, such as updated model parameters, with the NOR memory device via the second interface and the processing circuitry as part of performing a second operation of the one or more operations.

### CROSS REFERENCE

The present Application for Patent claims priority to U.S. Patent Application No. 63/744,740 by Pirovano et al., entitled “CHARGE TRAPPING FLASH NOR MEMORY IN MEMORY SYSTEMS,” filed January 13, 2025, which is assigned to the assignee hereof, and which is expressly incorporated by reference in its entirety herein.

### TECHNICAL FIELD

The following relates to one or more systems for memory, including charge trapping flash NOR memory in memory systems.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), Flash memory, phase change memory (PCM), 3-dimensional cross-point memory (3D cross point), NOR and NAND Flash memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NOR Flash, NAND) may maintain their programmed states for extended periods of time even in the absence of an external power source.

### BRIEF DESCRIPTION OF THE DRAWINGS

FIG. 1 shows an example of a system that supports charge trapping flash NOR memory in memory systems in accordance with examples as disclosed herein.

FIG. 2 shows an example of a memory device that supports charge trapping flash NOR memory in memory systems in accordance with examples as disclosed herein.

FIG. 3 shows an example of a memory system that supports charge trapping flash NOR memory in memory systems in accordance with examples as disclosed herein.

FIG. 4 shows a block diagram of a memory system that supports charge trapping flash NOR memory in memory systems in accordance with examples as disclosed herein.

FIG. 5 shows a flowchart illustrating a method or methods that support charge trapping flash NOR memory in memory systems in accordance with examples as disclosed herein.

### DETAILED DESCRIPTION

Some memory systems may be utilized for artificial intelligence (AI) applications. Such AI applications may involve increased read accesses that are associated with various latency metrics. Additionally, such AI applications may involve storing a relatively large quantity of data within volatile memory during execution of the AI application. For example, while executing an AI application (e.g., executing AI inference), a memory system may perform a relatively large quantity of read operations in quick succession to obtain data from a non-volatile memory device, such that the data may be transferred from non-volatile memory to volatile memory for execution. In such cases, however, some volatile memory devices may not have sufficient memory density (e.g., sufficient storage capacity) to store the increased quantity of data for AI applications (e.g., within a certain form factor or price point), may not be cost effective, or both. Additionally, some non-volatile memory devices may be associated with increased read latency and increased power consumption as compared to other systems, which may be insufficient for AI applications. Thus, memory solutions that provide for a higher memory density, while providing increased read performance at a lower power consumption may be desired.

The techniques, methods, and systems described herein enable a memory system to implement a charge trapping flash NOR memory device, which may be utilized by processing circuitry of the memory system to execute AI inference operations. For example, a memory system may include processing circuitry (e.g., one or more controllers) that is coupled with a NOR memory device via a first interface, where the first interface may be a read-only interface and utilize a first interface protocol. In such examples, the NOR memory device may store one or more model parameters associated with an AI application operated by the processing circuitry. Accordingly, to execute an AI inference operation, the processing circuitry may read (e.g., obtain, receive) the one or more model parameters from the NOR memory device via the first interface and execute the AI inference operation using the one or more model parameters, thereby bypassing the use of the volatile memory device during the AI inference operation.

By bypassing the transfer of the model parameters from another non-volatile memory device (e.g., not-AND memory device) to the volatile memory device (e.g., dynamic random-access memory (DRAM) device), the memory system may reduce latency associated with reading the data from the non-volatile memory device, and decrease power consumption, among other examples. Likewise, such NOR memory devices may have superior read performances and reduced power consumption during read operations relative to other non-volatile memory devices, which may be further reduce the latency associated with executing the AI inference operation. Additionally, because the volatile memory device may not be utilized during the AI inference operation, the capacity of the volatile memory device within the memory system may be reduced, thereby reducing costs associated with the memory device.

In addition to applicability in memory systems as described herein, techniques for charge trapping flash NOR memory in memory systems may be generally implemented to improve the performance of various electronic devices and systems (including AI applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds during AI interface operations at a memory system, which may decrease processing or latency times, improve response times, or otherwise improve user experience, among other benefits.

Features of the disclosure are illustrated and described in the context of systems and architectures. Features of the disclosure are further illustrated and described in the context of memory devices, memory systems, and flowcharts.

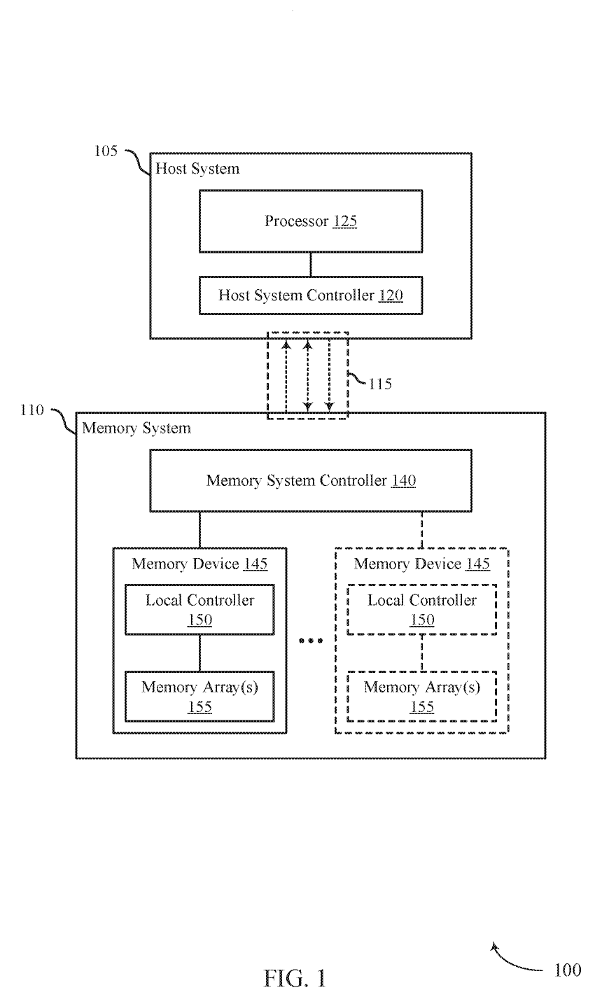

FIG. 1 shows an example of a system 100 that supports charge trapping flash NOR memory in memory systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations. In some examples, the memory system 110 may include three or more different types of memory devices 145. Such examples may include a first type of non-volatile memory device 145 (e.g., NAND), a second type of non-volatile memory device 145 (e.g., NOR), and a volatile memory device 145 (e.g., RAM, DRAM, SRAM, RRAM). More details about the interactions between the different types of memory devices (e.g., for AI applications) are described in more detail herein.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

The techniques, methods, and systems described herein enable the system 100 to implement a charge trapping flash NOR memory device in addition to the memory devices 145 (e.g., volatile memory devices), where the NOR memory device may be utilized by the memory system controller 140 and/or the host system controller 120 to execute AI inference operations. For example, the system 100 may include a NOR memory device coupled with processing circuitry (e.g., the host system controller 120 or the memory system controller 140) via a first interface, where the first interface may be a read-only interface and utilize a first interface protocol. In such examples, the NOR memory device may store one or more model parameters associated with an AI application operated by the processing circuitry. Accordingly, to execute an AI inference operation, the processing circuitry may read (e.g., obtain, receive) the one or more model parameters from the NOR memory device via the first interface and execute the AI inference operation using the one or more model parameters, thereby bypassing the use of the volatile memory device during the AI inference operation.

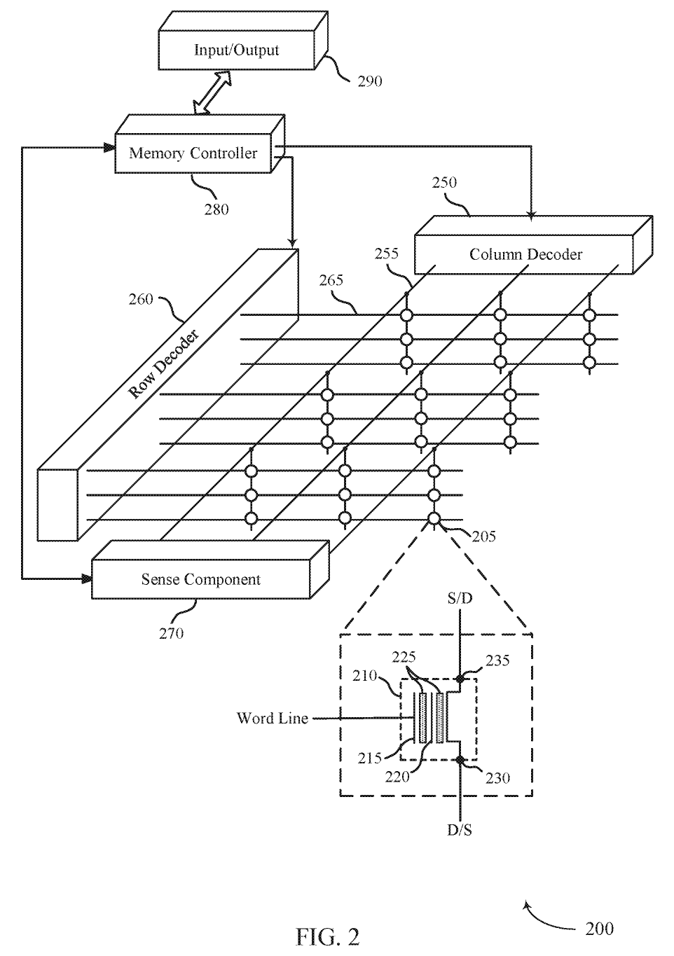

FIG. 2 illustrates an example of a memory device 200 that supports charge trapping flash NOR memory in memory systems in accordance with examples as disclosed herein. FIG. 2 is an illustrative representation of various components and features of the memory device 200. As such, the components and features of the memory device 200 are shown to illustrate functional interrelationships, and not necessarily physical positions within the memory device 200. Further, although some elements included in FIG. 2 are labeled with a numeric indicator, some other corresponding elements are not labeled, even though they are the same or would be understood to be similar, in an effort to increase visibility and clarity of the depicted features.

Developments in AI applications may lead to a memory solution that is capable of providing a high-density memory array combined with improved read performance (e.g., reduced latency and increased bandwidth) at a low cost, without increased write performances. AI applications may involve increased read operations having reduced latency metrics as compared to other applications, while also involving storing an increased quantity of data within a memory device. For example, AI applications may exhibit a different balance of read to write operations, as compared to other data storage applications, where write performance during AI inference operations may not be as vital to performance of the AI inference operations. For instance, in AI inference, a memory system may utilize static model data (e.g., model data is not updated during AI inference operations) and may perform a series of read operations to obtain the model data. While a NAND device has sufficient density to store the information for the AI applications, the NAND device read latency may be too large for AI applications. In such cases, during the AI inference operation, a memory system may transfer the model data from a NAND device to a DRAM device for execution.

However, such transference of model data, may lead to a memory system (e.g., a device, such as a mobile device or user equipment) implementing a relatively large DRAM capacity in order to manage large AI models. A large DRAM may be quite large and the memory system may experience increased power consumption during the AI inference operation, for example, due to transferring the model data from the NAND device to the DRAM device, due to refresh operations performed at the DRAM device to maintain the validity of model data stored in the DRAM device, or both. Thus, memory solutions that provide for a higher memory density, while providing increased read performance at a lower power consumption may be desired for AI inference operations.

According to the techniques described herein, a memory system may implement the memory device 200 to reduce read latencies and reduce power consumption during AI inference operations. The memory device 200 may offer superior read performance with improved (e.g., quicker) random access capability, reduced energy per bit (EPB) during read operations as compared to NAND memory, and support execute-in-place (XiP) capability (e.g., execution of programs is directly from the memory device 200, without first copying data into DRAM devices).

In some cases, the memory system may include a NOR non-volatile memory device for use during AI applications. For example, the memory system may include a memory device 200 coupled with processing circuitry via a first interface, where the first interface may be a read-only interface and utilize a first interface protocol. Further, the memory system may include a volatile memory device (e.g., DRAM device), where memory device 200 may be physically stacked in the same package as the volatile memory device and also share a same first interface (e.g., sharing the LPDDR bus). That is, the memory device 200 may be included in a stack of memory dies, where the stack of memory dies also includes one or more volatile memory devices (e.g., DRAM devices), and where the stack of memory dies shared a common bus that couples the stack of memory dies to the processing circuitry.

In some examples, the memory device 200 may store one or more model parameters associated with an AI application operated by the processing circuitry. Accordingly, to execute an AI inference operation, the processing circuitry may read (e.g., obtain, receive) the one or more model parameters from the memory device 200 via the first interface and execute the AI inference operation using the one or more model parameters, thereby bypassing the use of the volatile memory device during the AI inference operation.

The memory device 200 may include multiple charge trapping NOR Flash memory cells 205 in a pier and pillar architecture to increase the memory density (e.g., similar to 3D NAND three-bit-per-cell density) within the memory device 200 and improve read performance (e.g., have a relatively quicker random access speed, utilize decreased read voltages, have a higher bandwidth, among other advantages), while also reducing costs. For example, the memory device 200 may include multiple piers, where each pier may include multiple first memory cells 205 at a first end of the pier, and multiple second memory cells 205 at a second end of the pier.

To further increase the density (e.g., storage capacity) of the memory device 200, each memory cell 205 may be configured to store one or more bits of information. For example, each memory cell 205 may be configured as a single-level cell (SLC) to store a single bit of data or as a cell that stores two or more bits of data. For example, a memory cell 205 may be configured as a multi-level cell (MLC) that stores two bits of data, a triple-level cell (TLC) that stores three bits of data, a quad-level cell (QLC) that stores four bits of data, or a penta-level cell (PLC) that stores five bits of data. FIG. 2 illustrates a charge trapping NOR Flash memory cell 205 that includes a structure 210 that may be used to store two bits of data. The structure 210 may include a control gate 215 and a charge trapping structure 220, where the charge trapping structure 220 may, in some examples, be between two portions of dielectric material 225.

The structure 210 also may include a first node 230 (e.g., a source or drain) and a second node 235 (e.g., a drain or source). One or more logic values may be stored in the memory cell 205 by storing (e.g., writing) a quantity of electrons (e.g., an amount of charge) on the charge trapping structure 220. That is, the memory cell 205 may be programmed by trapping hot electrons into the charge trapping structure 220, where such electrons may be generated through channel-hot-electron mechanisms. Such charge trapping may occur at either side of the charge trapping structure 220 (e.g., at a first side to store a first bit of information and at a second side to store a second bit of information), thereby creating two bits of data store per memory cell 205.

As an illustrative example, each memory cell 205 may include a stack of materials including a first dielectric material 225 (e.g., gate oxide including silicon oxide, silicon nitride, or a silicon oxide multi-layer), a second dielectric material 225 (e.g., tunnel oxide including silicon oxide, silicon nitride, or a silicon oxide multi-layer), and a charge trapping structure 220 (e.g., silicon nitride) positioned between the dielectric materials 225.

Piers and pillars may be positioned in a two-dimensional array, where each pier may be positioned between a first pillar (e.g., source or drain) and a second pillar (e.g., drain or source) and be coupled with the first and second pillar via respective conductive paths, where such pillars may be utilized to access the memory cells at each pier. Each respective first memory cell 205 and each respective second memory cell 205 of a pier may be connected to a corresponding word line 265 (e.g., via the first dielectric material 225), where such word lines 265 may be utilized to access one of the multiple first memory cells or one of the multiple second memory cells. Each row of pillars may be connected to a respective source/drain (S/D) line (not shown) via a first transistor (thin film transistor) and each first transistor along each column of pillars may be connected to a corresponding bit line 255 (e.g., digit line or gate line). Accordingly, the S/D lines (e.g., access lines) may be perpendicular to the bit lines 255 (e.g., gate lines).

To access a memory cell 205, the column decoder 250 (e.g., gate line decoder) and a S/D decoder (not shown) may select the target memory cell 205 during programming (e.g., writing) or reading by biasing a single bit line 255 and two adjacent S/D lines, while the row decoder 260 may bias a word line 265 that corresponds to the memory cell 205. For example, the column decoder may activate a bit line 255, thereby selecting a column of pillars. Accordingly, the S/D decoder may select two adjacent S/D lines, thereby selecting a target pier, which may be positioned between the two selected pillars (e.g., the source and drain) on the selected column. Further, the row decoder 260 may bias the word line 265 that corresponds to the target memory cell 205.

As described herein, each pillar coupled with the target pier may be configured as a source or a drain according to which bit within the target memory cell 205 the memory device is to access. As such, to access a first bit of the target memory cell 205, the S/D decoder may configure the first pillar as a source by biasing the first pillar to a first voltage and may configure the second pillar as a drain by biasing the second pillar to a second voltage. Alternatively, to access the second bit of the target memory cell 205, the S/D decoder may configure the first pillar as a drain by biasing the first pillar to the second voltage and may configure the second pillar as a source by biasing the second pillar to the first voltage.

For example, to program a first bit of the target memory cell 205, the first pillar may be configured as the drain and biased to a first voltage (e.g., 5V), while the second pillar may be configured as the source and biased to a second voltage (e.g., 0V). The word line 265 associated with the target memory cell 205 may be biased to a third voltage (e.g., 9V). By doing so, a current may flow from the second pillar (e.g., the source) to the first pillar (e.g., the drain), thereby trapping hot electrons into the charge trapping structure 220 and programming the first bit.

Similarly, to program a second bit of the target memory cell 205, the second pillar may be configured as the drain and biased to a first voltage (e.g., 5V), while the first pillar may be configured as the source and biased to a second voltage (e.g., 0V). The word line 265 associated with the target memory cell 205 may be biased to a third voltage (e.g., 9V). By doing so, a current may flow from the first pillar (e.g., the source) to the second pillar (e.g., the drain), thereby trapping hot electrons into the charge trapping structure 220 and programming the second bit.

To read the first bit, the second pillar may be configured as the drain and biased to a first voltage (e.g., 1V), while the first pillar may be configured as the source and biased to a second voltage (e.g., 0V or ground). The word line 265 associated with the target memory cell 205 may be biased to a third voltage (e.g., 5V). By doing so, the sense component of the memory device 200 may sense the charge (e.g., first bit) stored in the charge trapping structure 220. Alternatively, to read the second bit, the first pillar may be configured as the drain and biased to a first voltage (e.g., 1V), while the second pillar may be configured as the source and biased to a second voltage (e.g., 0V or ground). The word line 265 associated with the memory cell 205 may be biased to a third voltage (e.g., 5V). By doing so, the sense component of the memory device 200 may sense the charge (e.g., second bit) stored in the charge trapping structure 220.

The memory cells 205 of the memory device 200 may be erased in blocks (e.g., sectors or groups) that include adjacent memory cells 205 associated with a same word line deck (e.g., same word line 265) across one or more piers. That is, to protect against over- or under-erasure, all bits in a block are pre-programmed and then all S/D contacts (e.g., pillars) in the block are positively biased for erasing all the bits in the block. Accordingly, each memory cell 205 within the block may be erased via a through hole injection or trapped-electrons extraction. For example, the memory controller 280 may verify that all bits stored in the memory cell 205 are in an erased state (e.g., store a logic value of ‘0’), the memory controller 280 may reprogram each of the respective two bits of the memory cells 205 to a uniform state (e.g., each bit is set to ‘1’). Based on reprogramming the bits to a logical ‘1’, the first and second pillars may be biased to a first voltage (e.g., 5V) and the word line 265 may be biased to a third voltage (e.g., -6V). By doing so, the bits of the memory cell may be erased.

A memory controller 280 may control the operation (e.g., read, write, re-write, refresh) of memory cells 205 through the various components (e.g., row decoder 260, column decoder 250, sense component 270, S/D decoder) and interface with an input/output function 290 (e.g., such as a host system). In some cases, one or more of a row decoder 260, a column decoder 250, a sense component 270, and a S/D decoder may be co-located with a memory controller 280. A memory controller 280 may generate row and column address signals in order to activate a desired word line 265, bit line 255, and adjacent S/D lines. In some examples, a memory controller 280 may generate and control various voltages or currents used during the operation of memory device 200.

In some examples, the memory device 200 may be referred to as a parallel memory device. For example, the memory device 200 may include multiple arrays of memory cells 205, where each of the memory cells 205 of an array have a parallel connection with decoding lines (e.g., word lines 265, S/D lines, bit lines 255, gate lines, among other examples). In contrast, a NAND memory device may be referred to as a serial memory device. For example, a NAND memory device may include multiple arrays of memory cells, where each of the memory cells of an array have a serial connection with decoding lines.

The techniques, methods, and systems described herein enable a memory system to implement memory device 200, where memory device 200 may be utilized by processing circuitry to execute AI inference operations. For example, a memory system may include the memory device 200 coupled with processing circuitry via a first interface, where the first interface may be a read-only interface and utilize a first interface protocol. In such examples, the memory device 200 may store one or more model parameters associated with an AI application operated by the processing circuitry. Accordingly, to execute an AI inference operation, the processing circuitry may read (e.g., obtain, receive) the one or more model parameters from the memory device 200 via the first interface and execute the AI inference operation using the one or more model parameters, thereby bypassing the use of the volatile memory device during the AI inference operation.

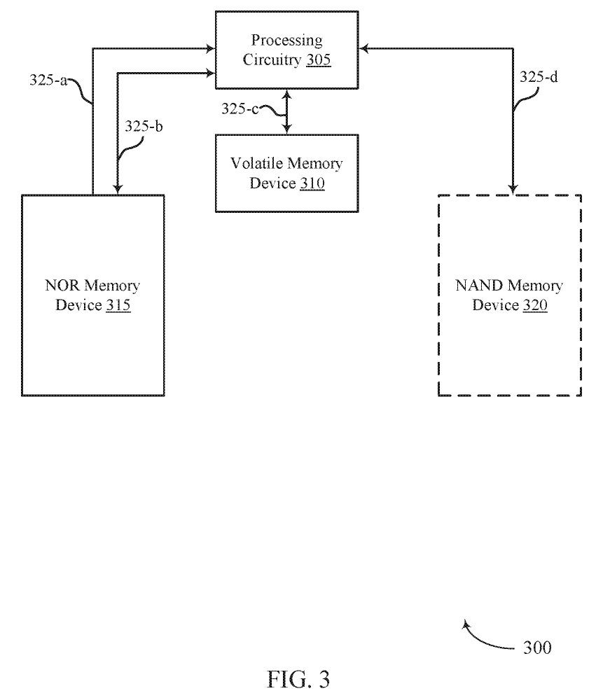

FIG. 3 shows an example of a memory system 300 that supports charge trapping flash NOR memory in memory systems in accordance with examples as disclosed herein. Aspects of the memory system 300 may implement, or be implemented by, aspects of the system 100 and the memory device 200, as described herein with reference to FIGS. 1 and 2. For example, the memory system 300 may include processing circuitry 305, which may be an example of a memory system controller 140, a host system controller 120, memory controller 280, a central processing unit (CPU), an inference engine, a graphics processing unit (GPU), or any combination thereof.

The memory system 300 may also include a volatile memory device 310, which may be an example of a memory system 110 or a memory device 145, as described herein with reference to FIG. 2. The memory system 300 may also include a NOR memory device 315, which may be an example of a memory device 200, as described herein with reference to FIG. 2. Further, the memory system 300 may include a NAND memory device 320, which may be an example of a solid state drive (SSD). The techniques described in the context of the memory system 300 may enable the processing circuitry 305 to perform AI inference operations using one or more model parameters (e.g., model data, model weights, data) stored in the NOR memory device 315.

Some other memory systems may be utilized for AI applications, where such AI applications may involve increased read accesses associated with various latency metrics. Execution of the AI applications may involve storing a relatively large quantity of data within volatile memory during execution of the AI application. For example, while operating some AI applications (e.g., executing AI inference), a memory system may perform a relatively large quantity of read operations in quick succession to obtain data from a non-volatile memory device, such that the data may be transferred from non-volatile memory to volatile memory for execution.

In such cases, however, some volatile memory devices may not have sufficient memory density (e.g., sufficient storage capacity) to store the increased quantity of data for AI applications in the form factors used by some memory systems, may not be cost effective, or both. For example, mobile units (such as smart phones) may have space constraints and power constraints (e.g., battery operated) that may make it challenging to have enough volatile memory (e.g., RAM) to operate AI applications within desired latencies. Some non-volatile memory devices (e.g., NAND) may have increased memory densities and reduced power consumption (as compared with RAM) but may have read latencies that are also too long for some AI applications. In another example, if multiple AI models are implemented, the volatile memory device may be incapable of loading the model parameters for the multiple AI models.

Additionally, some non-volatile memory devices may be associated with increased read latency and increased power consumption as compared to other systems, which may be insufficient for AI applications. To account for this, some non-volatile memory devices may implement a single level cell (SLC) cache along with a tri-level cell (TLC) SSD. However, read latencies associated with such non-volatile memory devices may still be unable to satisfy the various latency metrics for the AI applications. Thus, memory solutions that provide for a higher memory density, while providing increased read performance at a lower power consumption may be desired.

According to the techniques described herein, the memory system 300 may utilize the NOR memory device 315 to store model parameters associated with an AI application, such that the processing circuitry 305 may access the model parameters directly from the NOR memory device 315 during AI inference. For example, the processing circuitry 305 may be coupled with the processing circuitry 305 via an interface 325-a (e.g., a first interface) and an interface 325-b (e.g., a read and write interface). The processing circuitry may also be coupled with the volatile memory device 310 via the interface 325-c (e.g., a read and write interface) and be coupled with the NAND memory device 320 via the interface 325-d (e.g., a read and write interface).

To reduce read latencies during AI inference operations, the interface 325-a may be a read-only interface and operate according to a first interface protocol, such as a double data rate (DDR) protocol, a low power DDR (LPDDR) protocol, a graphics DDR (GDDR) protocol, a high bandwidth memory (HBM) protocol, or any combination thereof. Accordingly, the processing circuitry 305 may transmit one or more access commands to the NOR memory device 315 via the interface 325-b and write data to the NOR memory device 315 via the interface 325-b, which may enable the interface 325-a to have increased read performance.

In some examples, the NOR memory device 315 and the volatile memory device 310 may be part of a same stack of memory dies, where, in such examples, the interface 325-a and the interface 325-c may share a common pin at the processing circuitry 305. That is, the interface 325-a and the interface 325-c may be coupled with a same pin at the processing circuitry 305, where the processing circuitry 305 may utilize the common pin to communicate with both the volatile memory device 310 and the NOR memory device 315. In some other examples, the NOR memory device 315 and the volatile memory device 310 may be part of respective dies that are coupled with the processing circuitry 305.

The processing circuitry 305 may facilitate the communication of data between the volatile memory device 310, the NOR memory device 315, and the NAND memory device 320 according to the respective interfaces. As an illustrative example, the processing circuitry 305 may read data (e.g., user data) from the volatile memory device 310 via the interface 325-c and write the data to the NAND memory device 320 via the interface 325-d. Similarly, the processing circuitry 305 may read data from the NAND memory device 320 via the interface 325-d and write the data to the volatile memory device 310 via the interface 325-c.

In some examples, the NOR memory device 315 and the volatile memory device 310 may be coupled via a direct interface (not shown), where the direct interface may be utilized by the processing circuitry to communicate data between the volatile memory device 310 and the NOR memory device 315. Additionally, in some examples, the interface 325-b may couple the NOR memory device 315 with the volatile memory device 310 in addition to coupling the processing circuitry 305 with the NOR memory device 315. As such, the processing circuitry 305 may utilize the direct interface (not shown) and/or the interface 325-b (coupling the NOR memory device 315 to both the volatile memory device 310 and the processing circuitry 305) to communicate data between the volatile memory device 310 and the NOR memory device 315.

As described herein, the processing circuitry 305 may utilize the NOR memory device 315 to store one or more model parameters associated with an AI model. In such examples, the processing circuitry 305 may utilize the NAND memory device 320 to store user data (e.g., data other than model parameters). In some other examples, the memory system 300 may not include the NAND memory device 320, and instead, partition the NOR memory device 315 to store both model parameters and user data. That is, in some examples, a first portion (e.g., one or more first memory cells) of the NOR memory device 315 may store user data, while a second portion (e.g., one or more second memory cells) may store the one or more model parameters.

Prior to performing an AI inference operation, the processing circuitry 305 may utilize the volatile memory device 310 to generate one or more model parameters associated with an AI model. For example, the processing circuitry 305 may train the AI model on a data set to obtain the one or more model parameters, where the one or more model parameters may be written, temporarily or during the model training, to the volatile memory device 310 via the interface 325-c. Accordingly, in response to generating the one or more model parameters, the processing circuitry 305 may read the one or more model parameters from the volatile memory device 310 and store the one or more model parameters in the NOR memory device 315 via the interface 325-b.

According to generating the one or more model parameters, the processing circuitry may utilize the NOR memory device 315 to perform the AI inference operation. AI inference may be the process of using a trained machine learning model to make a prediction or decision (e.g., be the phase where the trained model is put into action). For example, the processing circuitry 305 may transmit, via the interface 325-b, one or more read commands to access the one or more model parameters at the NOR memory device 315. Based on (e.g., in response to) receiving the one or more read commands, the NOR memory device 315 may obtain (e.g., read or access) the one or more model parameters (e.g., either via a sequential read or random read based on the address of the one or more model parameters) and output the one or more model parameters to the processing circuitry 305 via the interface 325-a.

The processing circuitry 305 may perform a series of computations to produce a result, where such computations may involve matrix multiplications, convolutions, or other mathematical operations, depending on the type of model. In response to performing the series of computations, the processing circuitry may transform the result into an output, for example, by converting numeric scores into category labels, or applying a threshold to a probability. Based on obtaining the output, the processing circuitry 305 may transmit the output of the AI model to the end user or application, which may involve sending a response to a web request, or updating a database, among other examples.

In some examples, the processing circuitry 305 may update the one or more model parameters stored in the NOR memory device 315. To do so, the processing circuitry 305 may transmit one or more read commands to the NOR memory device 315 via the interface 325-b to read the one or more model parameters. In response, the NOR memory device 315 may output the one or more model parameters to the processing circuitry 305 via the interface 325-a. Accordingly, the processing circuitry 305 may perform a series of training computations on a data set and using the one or more model parameters to generate one or more update model parameters.

In some examples, the processing circuitry 305 may store the one or more updated model parameters, at least temporarily, in the volatile memory device 310 during the update operation. In response to generating the one or more updated model parameters, the processing circuitry 305 may write the one or more updated model parameters to the NOR memory device 315 via the interface 325-b.

By utilizing the NOR memory device 315 for the AI inference operation, the memory system 300 may bypass the transfer of the model parameters between the NAND memory device 320 to the volatile memory device 310 (e.g., RAM), thereby enabling the memory system 300 to reduce a capacity of the volatile memory device 310, leading to cost savings and/or power savings. Additionally, because the volatile memory device 310 may not be utilized during the AI inference operation, the memory system 300 may reduce the quantity of refresh operations performed at the volatile memory device 310, thereby reducing power consumption of the memory system 300. By implementing the NOR memory device 315, the memory system 300 may be capable of supporting relatively larger models (e.g., have terabyte (TB) capacity) because it has a higher memory density than volatile memory devices. Further, because the NOR memory device 315 supports native random read capability, the memory system 300 may experience a same bandwidth during both sequential and random read operations during the AI inference operation.

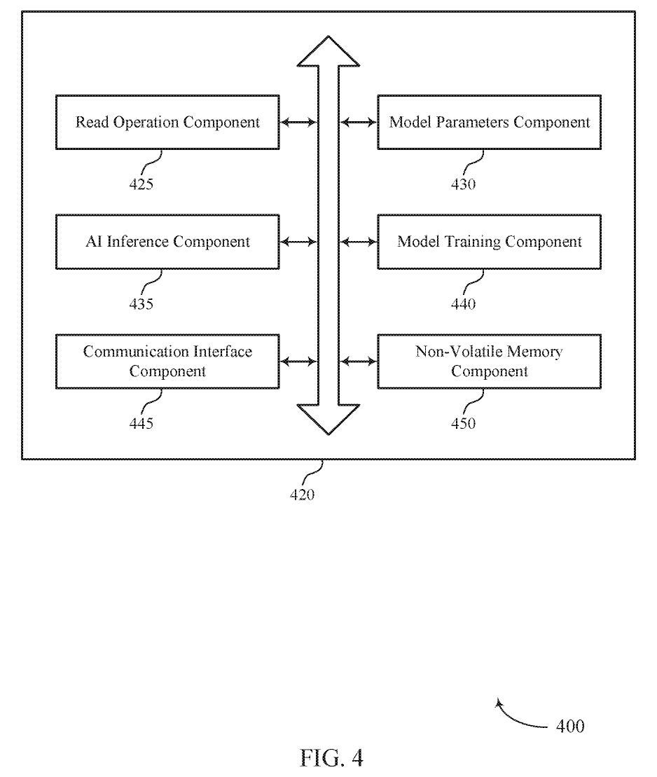

FIG. 4 shows a block diagram 400 of a memory system 420 that supports charge trapping flash NOR memory in memory systems in accordance with examples as disclosed herein. The memory system 420 may be an example of aspects of a memory system as described with reference to FIGS. 1 through 3. The memory system 420, or various components thereof, may be an example of means for performing various aspects of charge trapping flash NOR memory in memory systems as described herein. For example, the memory system 420 may include a read operation component 425, a model parameters component 430, an AI inference component 435, a model training component 440, a communication interface component 445, a non-volatile memory component 450, or any combination thereof. Each of these components, or components of subcomponents thereof (e.g., one or more processors, one or more memories), may communicate, directly or indirectly, with one another (e.g., via one or more buses).

The memory system 420 may support operating a memory system in accordance with examples as disclosed herein. The read operation component 425 may be configured as or otherwise support a means for communicating, from processing circuitry of the memory system to a NOR memory device of the memory system, one or more read commands directed to one or more model parameters associated with an AI model, where the NOR memory device includes a plurality of charge trapping flash NOR memory cells. The model parameters component 430 may be configured as or otherwise support a means for obtaining, at the processing circuitry from the NOR memory device via a first interface, the one or more model parameters in response to the one or more read commands. The AI inference component 435 may be configured as or otherwise support a means for executing, at the processing circuitry, an AI inference operation using the one or more model parameters in response to obtaining the one or more model parameters.

In some examples, the model training component 440 may be configured as or otherwise support a means for generating, by the processing circuitry, one or more updated model parameters in accordance with executing the AI inference operation and using a volatile memory device coupled with the processing circuitry via a second interface, where the volatile memory device includes a plurality of volatile memory cells. In some examples, the communication interface component 445 may be configured as or otherwise support a means for outputting, from the processing circuitry to the NOR memory device via a third interface, the one or more updated model parameters. In some examples, the non-volatile memory component 450 may be configured as or otherwise support a means for storing, at the NOR memory device, the one or more updated model parameters in response to output of the one or more updated model parameters.

In some examples, the first interface and the second interface are coupled with a common pin to communicate with the processing circuitry.

In some examples, the communication interface component 445 may be configured as or otherwise support a means for communicating data between the volatile memory device and a NAND memory device via a fourth interface and the processing circuitry, where the NAND memory device includes NAND memory cells.

In some examples, the first interface includes a read-only interface, the second interface includes a read and write interface, the third interface includes a read and write interface, and the fourth interface includes a read and write interface.

In some examples, each of the plurality of charge trapping flash NOR memory cells include a first dielectric material, a second dielectric material, and a charge trapping layer between the first dielectric material and the second dielectric material.

In some examples, each of the plurality of charge trapping flash NOR memory cells stores a first bit at a first end of the charge trapping layer based at least in part on trapping a first electron at the first end of the charge trapping layer, and each of the plurality of charge trapping flash NOR memory cells stores a second bit at a second end of the charge trapping layer based at least in part on trapping a second electron at the second end of the charge trapping layer.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

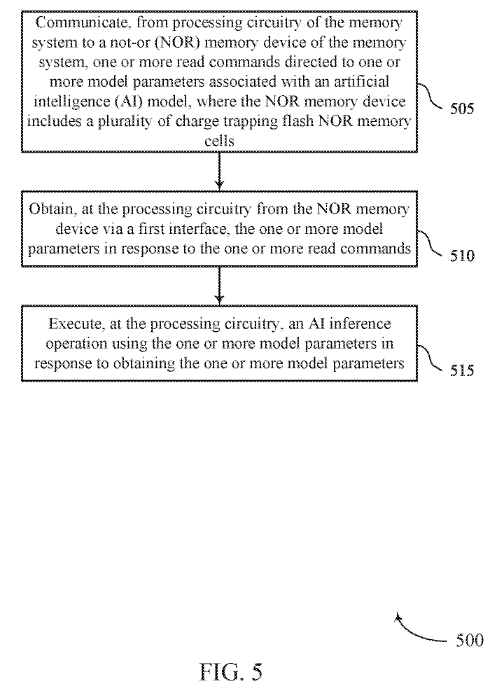

FIG. 5 shows a flowchart illustrating a method 500 that supports charge trapping flash NOR memory in memory systems in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include communicating, from processing circuitry of the memory system to a NOR memory device of the memory system, one or more read commands directed to one or more model parameters associated with an AI model, where the NOR memory device includes a plurality of charge trapping flash NOR memory cells. In some examples, aspects of the operations of 505 may be performed by a read operation component 425 as described with reference to FIG. 4.

At 510, the method may include obtaining, at the processing circuitry from the NOR memory device via a first interface, the one or more model parameters in response to the one or more read commands. In some examples, aspects of the operations of 510 may be performed by a model parameters component 430 as described with reference to FIG. 4.

At 515, the method may include executing, at the processing circuitry, an AI inference operation using the one or more model parameters in response to obtaining the one or more model parameters. In some examples, aspects of the operations of 515 may be performed by an AI inference component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for communicating, from processing circuitry of the memory system to a NOR memory device of the memory system, one or more read commands directed to one or more model parameters associated with an AI model, where the NOR memory device includes a plurality of charge trapping flash NOR memory cells; obtaining, at the processing circuitry from the NOR memory device via a first interface, the one or more model parameters in response to the one or more read commands; and executing, at the processing circuitry, an AI inference operation using the one or more model parameters in response to obtaining the one or more model parameters.

Aspect 2: The method, apparatus, or non-transitory computer-readable medium of aspect 1, further including operations, features, circuitry, logic, means, or instructions, or any combination thereof for generating, by the processing circuitry, one or more updated model parameters in accordance with executing the AI inference operation and using a volatile memory device coupled with the processing circuitry via a second interface, where the volatile memory device includes a plurality of volatile memory cells; outputting, from the processing circuitry to the NOR memory device via a third interface, the one or more updated model parameters; and storing, at the NOR memory device, the one or more updated model parameters in response to output of the one or more updated model parameters.

Aspect 3: The method, apparatus, or non-transitory computer-readable medium of aspect 2, where the first interface and the second interface are coupled with a common pin to communicate with the processing circuitry.

Aspect 4: The method, apparatus, or non-transitory computer-readable medium of any of aspects 2 through 3, further including operations, features, circuitry, logic, means, or instructions, or any combination thereof for communicating data between the volatile memory device and a NAND memory device via a fourth interface and the processing circuitry, where the NAND memory device includes NAND memory cells.

Aspect 5: The method, apparatus, or non-transitory computer-readable medium of aspect 4, where the first interface includes a read-only interface, the second interface includes a read and write interface, the third interface includes a read and write interface, and the fourth interface includes a read and write interface.

Aspect 6: The method, apparatus, or non-transitory computer-readable medium of any of aspects 1 through 5, where each of the plurality of charge trapping flash NOR memory cells include a first dielectric material, a second dielectric material, and a charge trapping layer between the first dielectric material and the second dielectric material.

Aspect 7: The method, apparatus, or non-transitory computer-readable medium of aspect 6, where each of the plurality of charge trapping flash NOR memory cells stores a first bit at a first end of the charge trapping layer based at least in part on trapping a first electron at the first end of the charge trapping layer, and each of the plurality of charge trapping flash NOR memory cells stores a second bit at a second end of the charge trapping layer based at least in part on trapping a second electron at the second end of the charge trapping layer.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: A memory system, including: processing circuitry configured to perform one or more operations; a NOR memory device coupled with the processing circuitry via a first interface and including NOR memory cells, where the NOR memory device is configured to provide first data to the processing circuitry via the first interface as part of performing a first operation of the one or more operations; and a volatile memory device coupled with the NOR memory device via a second interface and the processing circuitry, and including volatile memory cells, where the volatile memory device is configured to communicate with the NOR memory device via the second interface and the processing circuitry as part of performing a second operation of the one or more operations.

Aspect 9: The memory system of aspect 8, further including: a NAND memory device coupled with the volatile memory device via a third interface and the processing circuitry and including NAND memory cells, where the NAND memory device is configured to store second data associated with the one or more operations.

Aspect 10: The memory system of aspect 9, where: the NOR memory device includes a plurality of arrays, each array of the plurality of arrays includes a respective plurality of NOR memory cells, and the respective plurality of NOR memory cells of a corresponding array are coupled in parallel.

Aspect 11: The memory system of any of aspects 9 through 10, where: the NAND memory device includes a plurality of arrays, each array of the plurality of arrays includes a respective plurality of NAND memory cells, and the respective plurality of NAND memory cells of corresponding array are coupled in series.

Aspect 12: The memory system of any of aspects 8 through 11, where the volatile memory device is coupled with the processing circuitry via a third interface, and accessing the NOR memory device via the second interface is in accordance with one or more access commands received from the processing circuitry via the third interface.

Aspect 13: The memory system of aspect 12, where, for the volatile memory device to communicate with the NOR memory device, the memory system is configured to: communicate data between the volatile memory device and the processing circuitry via the third interface; and communicate the data between the processing circuitry and the NOR memory device via the second interface.

Aspect 14: The memory system of any of aspects 12 through 13, where the first interface and the third interface are coupled with a common pin to communicate with the processing circuitry.

Aspect 15: The memory system of any of aspects 12 through 14, where the first interface includes a read-only interface, the second interface includes a read and write interface, and the third interface includes a read and write interface.

Aspect 16: The memory system of any of aspects 8 through 15, where the NOR memory device and the volatile memory device include a stack of memory dies, and the stack of memory dies is coupled with the processing circuitry via the first interface.

Aspect 17: The memory system of any of aspects 8 through 16, where the one or more operations are performed as part of implementing an AI model, and the first data includes one or more model parameters associated with the AI model.

Aspect 18: The memory system of aspect 17, where the first operation includes an AI inference operation using the one or more model parameters.

Aspect 19: The memory system of any of aspects 17 through 18, where the processing circuitry is configured to update the one or more model parameters via the volatile memory device and the second interface as part of performing the second operation.

Aspect 20: The memory system of any of aspects 8 through 19, where the NOR memory cells each include a first dielectric material, a second dielectric material, and a charge trapping layer between the first dielectric material and the second dielectric material.

Aspect 21: The memory system of aspect 20, where a NOR memory cell of the NOR memory cells stores a first bit at a first end of the charge trapping layer based at least in part on trapping a first electron at the first end of the charge trapping layer, and stores a second bit at a second end of the charge trapping layer based at least in part on trapping a second electron at the second end of the charge trapping layer.

Aspect 22: The memory system of any of aspects 8 through 21, where the NOR memory device is a non-volatile memory device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
processing circuitry configured to perform one or more operations;
a not-or (NOR) memory device coupled with the processing circuitry via a first interface and comprising NOR memory cells, wherein the NOR memory device is configured to provide first data to the processing circuitry via the first interface as part of performing a first operation of the one or more operations; and
a volatile memory device coupled with the NOR memory device via a second interface and the processing circuitry, and comprising volatile memory cells, wherein the volatile memory device is configured to communicate with the NOR memory device via the second interface and the processing circuitry as part of performing a second operation of the one or more operations.

2. The memory system of claim 1, further comprising:
a not-AND (NAND) memory device coupled with the volatile memory device via a third interface and the processing circuitry and comprising NAND memory cells, wherein the NAND memory device is configured to store second data associated with the one or more operations.

3. The memory system of claim 2, wherein:
the NOR memory device comprises a plurality of arrays,
each array of the plurality of arrays comprises a respective plurality of NOR memory cells, and
the respective plurality of NOR memory cells of a corresponding array are coupled in parallel.

4. The memory system of claim 2, wherein:
the NAND memory device comprises a plurality of arrays,
each array of the plurality of arrays comprises a respective plurality of NAND memory cells, and
the respective plurality of NAND memory cells of corresponding array are coupled in series.

5. The memory system of claim 1, wherein:
the volatile memory device is coupled with the processing circuitry via a third interface, and
accessing the NOR memory device via the second interface is in accordance with one or more access commands received from the processing circuitry via the third interface.

6. The memory system of claim 5, wherein, for the volatile memory device to communicate with the NOR memory device, the memory system is configured to:
communicate data between the volatile memory device and the processing circuitry via the third interface; and
communicate the data between the processing circuitry and the NOR memory device via the second interface.

7. The memory system of claim 5, wherein the first interface and the third interface are coupled with a common pin to communicate with the processing circuitry.

8. The memory system of claim 5, wherein the first interface comprises a read-only interface, the second interface comprises a read and write interface, and the third interface comprises a read and write interface.

9. The memory system of claim 1, wherein:
the NOR memory device and the volatile memory device comprise a stack of memory dies, and
the stack of memory dies is coupled with the processing circuitry via the first interface.

10. The memory system of claim 1, wherein:
the one or more operations are performed as part of implementing an artificial intelligence (AI) model, and
the first data comprises one or more model parameters associated with the AI model.

11. The memory system of claim 10, wherein the first operation comprises an AI inference operation using the one or more model parameters.

12. The memory system of claim 10, wherein the processing circuitry is configured to update the one or more model parameters via the volatile memory device and the second interface as part of performing the second operation.

13. The memory system of claim 1, wherein the NOR memory cells each comprise a first dielectric material, a second dielectric material, and a charge trapping layer between the first dielectric material and the second dielectric material.

14. The memory system of claim 13, wherein a NOR memory cell of the NOR memory cells stores a first bit at a first end of the charge trapping layer based at least in part on trapping a first electron at the first end of the charge trapping layer, and stores a second bit at a second end of the charge trapping layer based at least in part on trapping a second electron at the second end of the charge trapping layer.

15. The memory system of claim 1, wherein the NOR memory device is a non-volatile memory device.

16. A memory system, comprising:
a not-or (NOR) memory device; and
processing circuitry coupled with the NOR memory device and configured to cause the memory system to:
communicate, from the processing circuitry to the NOR memory device, one or more read commands directed to one or more model parameters associated with an artificial intelligence (AI) model, wherein the NOR memory device comprises a plurality of charge trapping flash NOR memory cells;
obtain, at the processing circuitry from the NOR memory device via a first interface, the one or more model parameters in response to the one or more read commands; and
execute, at the processing circuitry, an AI inference operation using the one or more model parameters in response to obtaining the one or more model parameters.

17. The memory system of claim 16, wherein the memory system further comprises a volatile memory device coupled with the processing circuitry via a second interface, and wherein the processing circuitry is configured to cause the memory system to:
generate, by the processing circuitry, one or more updated model parameters in accordance with executing the AI inference operation and using the volatile memory device, wherein the volatile memory device comprises a plurality of volatile memory cells;
output, from the processing circuitry to the NOR memory device via a third interface, the one or more updated model parameters; and
store, at the NOR memory device, the one or more updated model parameters in response to output of the one or more updated model parameters.

18. The memory system of claim 17, wherein the first interface and the second interface are coupled with a common pin to communicate with the processing circuitry.

19. The memory system of claim 17, wherein the memory system further comprises a not-AND (NAND) memory device coupled with the processing circuitry via a fourth interface, and wherein the processing circuitry is configured to cause the memory system to:
communicate data between the volatile memory device and the NAND memory device via the fourth interface and the processing circuitry, wherein the NAND memory device comprises a plurality of NAND memory cells.

20. The memory system of claim 19, wherein the first interface comprises a read-only interface, the second interface comprises a read and write interface, the third interface comprises a read and write interface, and the fourth interface comprises a read and write interface.

21. The memory system of claim 16, wherein each of the plurality of charge trapping flash NOR memory cells comprise a first dielectric material, a second dielectric material, and a charge trapping layer between the first dielectric material and the second dielectric material.

22. The memory system of claim 21, wherein each of the plurality of charge trapping flash NOR memory cells stores a first bit at a first end of the charge trapping layer based at least in part on trapping a first electron at the first end of the charge trapping layer, and each of the plurality of charge trapping flash NOR memory cells stores a second bit at a second end of the charge trapping layer based at least in part on trapping a second electron at the second end of the charge trapping layer.

23. A method for operating a memory system, comprising:
communicating, from processing circuitry of the memory system to a not-or (NOR) memory device of the memory system, one or more read commands directed to one or more model parameters associated with an artificial intelligence (AI) model, wherein the NOR memory device comprises a plurality of charge trapping flash NOR memory cells;
obtaining, at the processing circuitry from the NOR memory device via a first interface, the one or more model parameters in response to the one or more read commands; and
executing, at the processing circuitry, an AI inference operation using the one or more model parameters in response to obtaining the one or more model parameters.
